(19) United States
(12) Patent Application Publication
(10) Pub. No.: US 2025/0105705 A1
(43) Pub. Date: Mar. 27, 2025

(54) MOTOR ARRANGEMENTS, SEMICONDUCTOR PROCESSING SYSTEMS HAVING MOTOR ARRANGEMENTS AND RELATED METHODS OF PURGING MOTOR ARRANGEMENTS IN SEMICONDUCTOR PROCESSING SYSTEMS

(71) Applicant: ASM IP Holding B.V., Almere (NL)

(72) Inventors: Mario Gonzalez, Phoenix, AZ (US); Joseph Kraus, Brandon, FL (US); Dongyang Chen, Chandler, AZ (US); Shaofeng Chen, Austin, TX (US)

(21) Appl. No.: 18/893,498

(22) Filed: Sep. 23, 2024

Related U.S. Application Data
(60) Provisional application No. 63/540,267, filed on Sep. 25, 2023.

(51) Int. Cl. H02K 9/26; B25J 9/10; H01L 21/67; H01L 21/687; H02K 21/14

(52) U.S. Cl. CPC H02K 9/26; B25J 9/106; H01L 21/67196; H01L 21/68707; H02K 21/14

(57) ABSTRACT

A motor arrangement includes a stator body, a rotor body, a permanent magnet and a fluid conduit. The stator body defines a rotary axis and has a bore. The rotor body is supported for rotary movement about the rotary axis in the bore and is separated from the stator body by a gap. The permanent magnet is arranged within the gap and is fixed to one of the stator body and the rotor body. The fluid conduit is supported above the gap and has an outlet in fluid communication with the gap to separate the permanent magnet from an infiltrant fluid resident within an atmosphere above of the gap by issuing a barrier fluid into the atmosphere above the gap and gravimetrically flowing the barrier fluid into the gap. Semiconductor processing systems, barrier fluid kits, and methods of purging motor arrangements are also described.

### CROSS-REFERENCE TO RELATED APPLICATION(S)

This Application claims the benefit of U.S. Provisional Application 63/540,267 filed on Sep. 25, 2023, the entire contents of which are incorporated herein by reference.

### FIELD OF INVENTION

The present disclosure generally relates to motor arrangements, and more particularly to motor arrangements having permanent and employed to transfer substrates in semiconductor processing systems.

### BACKGROUND OF THE DISCLOSURE

Semiconductor devices are commonly fabricated by loading a substrate into a process chamber of a semiconductor processing system and processing the substrate. Once processing is complete the substrate is generally removed from the process chamber and transferred to another process module to undergo further processing, as appropriate for the semiconductor device being fabricated. Loading and unloading of the substrate may be accomplished using a transfer robot, which is typically located outside of the process chamber and environmentally separated from the process chamber.

During fabrication of some semiconductor devices processing may be accomplished by exposing the substrate to potentially corrosive and/or disintegrative fids to structures within the semiconductor processing system employed for fabricating the semiconductor devices. To limit risk of exposure to such fluids the processing environment within which the potentially corrosive and/or disintegrative fluid is typically separated from environments housing structures potentially subject to corrosion and/or disintegration by such fluids. For example, the process space within the potentially corrosive and/or disintegrative fluid is employed may include a gate valve, which remains closed during processing and is only opened to the interior of the semiconductor processing system for substrate transfer after the process space has been evacuated to remove potentially corrosive and/or disintegrative fluids from the process space. While generally satisfactory for its intended, residual corrosive and/or potentially corrosive fluids may nevertheless infiltrate the interior of the semiconductor processing system during transfer of substrates to and from the process space, for example due to pressure imbalances within the semiconductor processing system or due to adsorption from the surfaces of the substrates being transferred between the process space and the interior of the semiconductor processing system outside of process space.

Various countermeasures exist to prevent corrosive and/or disintegrative fluids employed during substrate processing from escaping process modules in semiconductor processing systems. For example, gate valves coupling the environment inhabited by the transfer robot to process modules employing corrosive fluid and/or disintegrative fluids may include sealing features to ensure that the gate valve is fluid-tight, such as corrosive-resistant gaskets and corrosion-resistant sealing surfaces. Substrate transfer may be delayed subsequent to processing to provide additional time to ensure that residual corrosive and/or disintegrative fluids are removed from the process chamber prior opening the gate valve. And structures subject to exposure to potentially corrosive and/or disintegrative fluids may be formed from material resistant to corrosion and/or disintegration by the fluids.

Such systems and methods have generally been considered suitable for their intended purpose. However, there remains a need in the art for improved purge arrangements, substrate transfer robots and semiconductor processing systems having purge arrangements, and related methods of purging motor arrangements such as in semiconductor processing systems. The present disclosure provides a solution to this need.

### SUMMARY OF THE DISCLOSURE

A motor arrangement is provided. The motor arrangement includes a stator body, a rotor body, a permanent magnet and a fluid conduit. The stator body defines a rotary axis and has a bore. The rotor body is supported for rotary movement about the rotary axis in the bore and is separated from the stator body by a gap. The permanent magnet is arranged within the gap and is fixed to one of the stator body and the rotor body. The fluid conduit is supported above the gap and has an outlet that is in fluid communication with the gap to separate the permanent magnet from an infiltrant fluid resident within an atmosphere above of the gap by issuing a barrier fluid into the atmosphere above the gap and gravimetrically flowing the barrier fluid into the gap.

In addition to one or more of the features described above, or as an alternative, further examples of the motor arrangement may include that the bore is a blind bore. The rotor body may extend axially from the bore and into the atmosphere above the gap defined between the stator body and the rotor body.

In addition to one or more of the features described above, or as an alternative, further examples of the motor arrangement may include that the permanent magnet is formed from a magnetic material including neodymium. The permanent magnet may have a nickel coating.

In addition to one or more of the features described above, or as an alternative, further examples of the motor arrangement may include the permanent magnet is one of a plurality of permanent magnets carried by the rotor body. The plurality of permanent magnets may be distributed circumferentially about the rotary axis.

In addition to one or more of the features described above, or as an alternative, further examples of the motor arrangement may include a barrier fluid source connected to the fluid conduit. The barrier fluid source may contain a barrier fluid and be configured to flow the barrier fluid to gap defined between the stator body and the rotor body through the outlet of the fluid conduit.

In addition to one or more of the features described above, or as an alternative, further examples of the motor arrangement may include that the barrier fluid has a density greater that is greater than that of the infiltrant fluid.

In addition to one or more of the features described above, or as an alternative, further examples of the motor arrangement may include that the barrier fluid has a density greater than that of hydrochloric (HCl) acid and hydrogen (H₂) gas in an evacuated atmosphere and at about room temperature.

In addition to one or more of the features described above, or as an alternative, further examples of the motor arrangement may include link and an end effector. The link may be pivotably connected to the rotor body and extend laterally from the rotor body within the atmosphere above the gap between the rotor body and the stator body. The end effector may be connected the link and configured to carry a substrate within the atmosphere above the gap defined between the stator body and the rotor body.

In addition to one or more of the features described above, or as an alternative, further examples of the motor arrangement may include a substrate transfer chamber body. The substrate transfer chamber body may have a lower wall defining a robot seat. The stator body of the motor arrangement may be fixed to the robot seat and extend below the lower wall of the substrate transfer chamber body.

A semiconductor processing system is provided. The semiconductor processing system includes a motor arrangement as described above and a substrate transfer chamber body. The substrate transfer chamber body has a facet and a lower wall defining a robot seat. The stator body of the motor arrangement is fixed within the robot seat and protrudes below the lower wall of the substrate transfer chamber body. The rotor body of the motor arrangement protrudes above the lower wall of the substrate transfer chamber body and into the interior of the substrate transfer chamber body. The fluid conduit of the motor arrangement is separated from the facet by the rotor body of the motor arrangement.

In addition to one or more of the features described above, or as an alternative, further examples of the semiconductor processing system may include that the lower wall of the substrate transfer chamber body defines a passthrough. The fluid conduit may include a vertical segment coupled to a horizontal segment by a union or arcuate segment. The vertical segment may extend through the passthrough, the union or arcuate segment may couple the vertical segment to the horizontal segment, and the horizontal segment may couple the union or arcuate segment to the outlet of the fluid conduit.

In addition to one or more of the features described above, or as an alternative, further examples of the semiconductor processing system may include a barrier fluid source and a vacuum source. The barrier fluid source may be connected to the fluid conduit to issue a barrier fluid into the interior of the substrate transfer chamber body above the gap defined between the stator body and the rotor body of the motor arrangement. The vacuum source may be connected to the substrate transfer chamber body to evacuate the interior of the substrate transfer chamber body.

In addition to one or more of the features described above, or as an alternative, further examples of the semiconductor processing system may include a first fluid source and a second fluid source. The first fluid source may be coupled to the facet of the substrate transfer chamber body and include a first fluid, the second fluid source may be coupled to the facet of the substrate transfer chamber body and include a second fluid, the first fluid contained in the first fluid source is apt to infiltrate the interior of the substrate transfer chamber body and therethrough the gap between the rotor body and the stator of the motor arrangement through the facet of the substrate transfer chamber body, and the second fluid contained in the second fluid source is apt to infiltrate the interior of the substrate transfer chamber body and therethrough the gap between the rotor body and the stator of the motor arrangement through the facet of the substrate transfer chamber body.

In addition to one or more of the features described above, or as an alternative, further examples of the semiconductor processing system may include that the permanent magnet has a protective coating, that the first fluid is corrosive to the protective coating, and that the first fluid may be less dense than the barrier fluid when the first fluid and the barrier fluid reside within an evacuated atmosphere contained within the interior of the substrate transfer chamber body.

In addition to one or more of the features described above, or as an alternative, further examples of the semiconductor processing system may include that the permanent magnet is formed from a bulk magnetic material, that the second fluid is disintegrative to the bulk magnetic material forming the permanent magnet, and that the second fluid is less dense than the barrier fluid when the second fluid and the barrier fluid reside within an evacuated atmosphere contained within the interior of the substrate transfer chamber body.

In addition to one or more of the features described above, or as an alternative, further examples of the semiconductor processing system may include that the interior of the substrate transfer chamber body contains an evacuated atmosphere, that the gap defined between the stator body and the rotor body is in fluid communication with the interior of the substrate transfer chamber body, and that the barrier fluid resides within the gap defined between the stator body and the rotor body of the motor arrangement.

In addition to one or more of the features described above, or as an alternative, further examples of the semiconductor processing system may include that the permanent magnet is formed from neodymium (Nd) and has a nickel (Ni) coating. Infiltrant hydrogen (H₂) gas and hydrochloric (HCl) acid may be resident within the evacuated atmosphere contained within the interior of the substrate transfer chamber body, the barrier fluid may include argon (Ar) gas, and the barrier gas may separate permanent magnet from the infiltrant hydrogen (H₂) gas and the hydrochloric (HCl) acid resident within the atmosphere above the gap.

In addition to one or more of the features described above, or as an alternative, further examples of the semiconductor processing system may include a link, an end effector, and a process module. The link may pivotably depend from the rotor body. The end effector may depend from the link and be configured to carry a substrate. The process module may be coupled to the facet of the substrate transfer chamber body and configured to one or more of etch the substrate and deposit a material layer onto the substrate. The facet may be one of a plurality of facets distributed about the robot seat and extending upwards from the lower wall of the substrate transfer chamber body and the barrier fluid is consists essentially of one of helium (He) gas, argon (Ar) gas, krypton (Kr) gas, neon (Ne) gas, and xenon (Xe) gas.

A method of purging a motor arrangement is provided. The method includes, at a motor arrangement as described above, issuing a barrier fluid from the outlet of the fluid conduit into an atmosphere above the gap, gravimetrically flowing the barrier fluid into the gap defined between the stator body and the rotor body, and separating the permanent magnet from an infiltrant fluid potentially corrosive and/or disintegrative to the permanent magnet resident in the atmosphere above of the gap using the barrier fluid to prolong an expected service life of the motor arrangement.

A barrier fluid kit for a motor arrangement as described above is provided. The barrier fluid kit includes a fluid conduit with an outlet to issue a barrier fluid into the substrate transfer chamber body and flow the barrier fluid into the gap, a barrier supply valve to couple a barrier fluid source to the fluid conduit, and a computer program product. The computer program product includes instructions recorded on a non-transitory machine readable medium that, when read by a processor operatively connected to the barrier supply valve, cause the barrier fluid supply valve to issue a barrier fluid from the outlet of the fluid conduit into an atmosphere above the gap according to movement of the rotor body relative to the stator body, the barrier fluid gravimetrically flowing into the gap, and the barrier fluid separating the permanent magnet from an infiltrant fluid potentially corrosive and/or disintegrative to the permanent magnet resident in the atmosphere above of the gap to prolong an expected service life of the motor arrangement.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a plan view of a semiconductor processing system including a motor arrangement in accordance with the present disclosure, showing the motor arrangement operably connected to a substrate transfer robot housed within a substrate transfer module;

FIG. 2 is a cross-sectional side view of the semiconductor processing system of FIG. 1 according to an example of the present disclosure, schematically showing a barrier fluid source coupled to the motor arrangement by a fluid to issue a barrier fluid into the module;

FIGS. 3-6 are perspective and cross-sectional views of the motor arrangement and a permanent magnet included in the motor arrangement, schematically showing the fluid conduit issuing a barrier fluid into an atmosphere within the substrate transfer module;

FIGS. 7-10 are a block diagram of a substrate transfer method in accordance with the present disclosure, showing operations of the method according to an illustrative and non-limiting example of the present disclosure; and

FIGS. 11 and 12 are block diagrams of a barrier fluid kit and a method making a semiconductor processing system using the barrier fluid kit, showing components of the barrier fluid kit and operations of the method according to examples of the disclosure, respectively.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

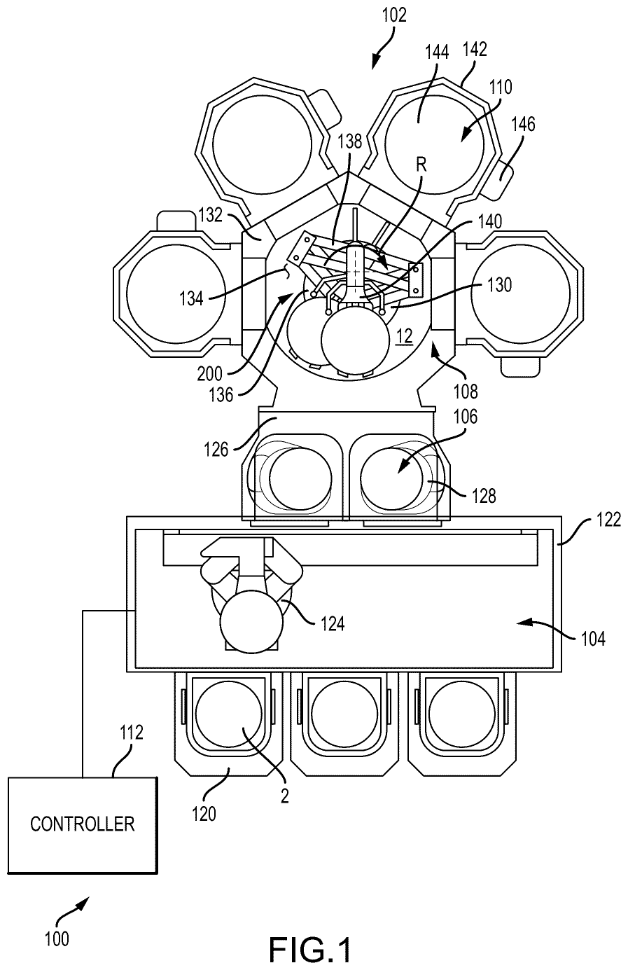

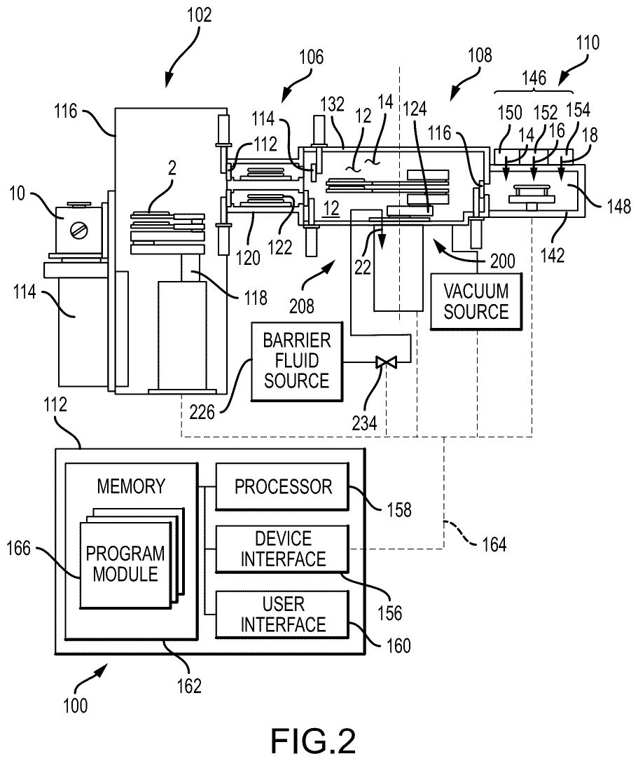

Reference will now be made to the drawings wherein like reference numerals identify similar structural features or aspects of the subject disclosure. For purposes of explanation and illustration, and not limitation, a partial view of an example of a semiconductor processing system with a motor arrangement in accordance with the present disclosure is shown in FIG. 1 and is designated generally by reference character 100. Other examples of motor arrangements, semiconductor processing systems, barrier fluid kits and methods of purging motor arrangements, or aspects thereof, are provided in FIGS. 2-12, as will be described. The systems and methods of the present disclosure may be used to purge motor arrangements from fluids in motor arrangement operating environment, such as to separate permanent magnets employed in substrate transfer robot drive motors from potentially corrosive and/or disintegrative fluids resident within atmospheres contained within semiconductor processing system, though the present disclosure is not limited to any particular type of fluid, motor or to semiconductor processing systems in general.

Referring to FIG. 1, the semiconductor processing system 100 is shown. As shown in FIG. 1 the semiconductor processing system 100 has a cluster-type arrangement 102 and includes an equipment front-end module (EFEM) 104, a loadlock module 106, a substrate transfer module 108, and a process module 110. As shown and described herein the semiconductor processing system 100 also includes a front-end gate valve 112 (shown in FIG. 2), a back-end gate valve 114 (shown in FIG. 2), a process module gate valve 116 (shown in FIG. 2), and a controller 118. Although shown and described herein as including specific elements and having a specific arrangement, a cluster-type platform having four (4) single chamber process modules, it is to be understood and appreciated that semiconductor processing systems having other arrangement may also benefit from the present disclosure.

The EFEM 104 includes a load port 120, an enclosure 122, and a front-end substrate transfer robot 124. The load port 120 is connected to the enclosure 122 and is configured to there a pod 10 housing a substrate 2, such as a standard mechanical interface (SMIF) pod or a front-opening unified pod (FOUP). The enclosure 122 is coupled to the loadlock module 106 and houses the front-end substrate transfer robot 124. The front-end substrate transfer robot 124 is supported for movement in the enclosure 122 and configured to transfer the substrate 2 between the load port 120 and the loadlock module 106. In the illustrated example the load port 120 is one of three (3) load ports. As will be appreciated by those off skill in the art in view of the present disclosure, the EFEM 104 may include fewer or additional load ports than shown and described herein and remain within the scope of the present disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, a 200-millimeter or a 300-millimeter wafer. A substrate may be formed from a semiconductor material, including, for example, silicon (Si), silicon-germanium (SiGe), silicon oxide (SiO₂), gallium arsenide (GaAs), gallium nitride (GaN) and silicon carbide (SiC). A substrate may include a pattern or may unpatterned.

The loadlock module 106 includes a loadlock chamber body 126 and a set plate 128. The loadlock chamber body 126 is coupled to the EFEM 104 by the front-end gate valve 112 (shown in FIG. 2), in turn couples the EFEM 104 to the substrate transfer module 108 and houses within its interior the set plate 128. The set plate 128 is configured to support the substrate 2 during transfer between the EFEM 104 and substrate transfer module 108 and in this respect is within the mechanical reach of end effectors operably associated with the front-end substrate transfer robot 124 and a back-end substrate transfer robot 130 included in the substrate transfer module 108. In the illustrated example the loadlock module 106 includes four (4) chambers each housing two (2) set plates. As will be appreciated by those of skill in the art in view of the present disclosure, the loadlock module 106 may include fewer or additional chambers and remain within the scope of the present disclosure. As will also be appreciated by those of skill in the art in view of the present disclosure, the loadlock module 106 may also include fewer or additional set plates than shown and described herein and remain within the scope of the present disclosure.

The substrate transfer module 108 includes a substrate transfer chamber body 132,

the back-end substrate transfer robot 130, and the motor arrangement 200. The substrate transfer chamber body 132 is coupled to the loadlock chamber body 126 by the back-end gate valve 114, is in turn coupled to the process module 110 and houses the back-end substrate transfer robot 130. The back-end substrate transfer robot 130 is supported for movement within the interior of the substrate transfer chamber body 132 (e.g., within an atmosphere 12 contained with the substrate transfer chamber body 132) and is configured to transfer the substrate 2 between the loadlock module 106 and the process module 110. In this respect it is contemplated that the back-end substrate transfer robot 130 be seated in a lower wall 134 of the substrate transfer chamber body 132 at a robot seat 136 and be operably associated with the motor arrangement 200. In further respect, the back-end substrate transfer robot 130 may include one or more link 138 and one or more end effector 140, the one or more link 138 configured to provide mechanical reach, and the one or more end effector 140 configured to carry the substrate between the loadlock module 106 and the process module 110. As shown and described herein the semiconductor processing system 100 includes a single substrate transfer module 108. As will be appreciated by those of skill in the art in view of the present disclosure, semiconductor processing systems having more than one substrate transfer module may also benefit from the present disclosure.

The process module 110 includes a process chamber body 142, a substrate support 144, and a fluid supply 146. The process chamber body 142 is coupled to the substrate transfer module 108 by the process module gate valve 116 and defines a process space 148 within its interior. The substrate support 144 is arranged within the interior of the process chamber body 142 and is configured to support the substrate 2 during processing, for example during deposition of a material layer 4 onto the substrate 2 such as using a chemical vapor deposition (CVD) technique or an atomic layer deposition (ALD) technique and/or during removal of material 6 from the substrate 2 such as during a preclean or surface preparation technique. In this respect it is contemplated that the substrate support 144 be within mechanical reach of the back-end substrate transfer robot 130 and be supported within the process chamber body 142 such that the substrate support 144 presents the substrate 2 to the process space 148 (shown in FIG. 2) for exposure to a fluid provided by the fluid supply 146 to process the substrate 2. As shown and described herein the process module 110 is one of four (4) process modules coupled to process facets of the substrate transfer module 108. As will be appreciated by those of skill in the art in view of the present disclosure, the semiconductor processing system 100 may have fewer or additional process modules than shown and described herein and remain within the scope of the present disclosure.

With reference to FIG. 2, it is contemplated that the fluid supply 146 be connected to the process chamber body 142 and configured to provide a flow of one or more process fluid to the process space 148 within the process chamber body 142. In this respect the fluid supply 146 may include a plurality of fluid sources, for example a first fluid source 150, a second fluid source 152 and a third fluid source 154. The first fluid source 150 may include a first fluid 14 and be configured to provide a flow of the first fluid 14 to the process chamber body 142 and therethrough to the process space 148 therein, the second fluid source 152 may include a second fluid 16 and be configured to provide a flow of a second fluid 16 to the process chamber body 142 and therethrough to the process space 148 therein, and the third fluid source 154 may include the third fluid 18 and be configured to provide a flow of the third fluid 18 to the process chamber body 142 and therethrough to the process space 148 therein. As will be appreciated by those of skill in the art in view of the present disclose, although shown and described herein as providing three (3) fluids to the process chamber body 142, the fluid supply 146 may provide fewer or additional fluids to the process chamber body 142 in other examples of the present disclosure and remain within the scope of the present disclosure.

In certain examples of the present disclosure, the first fluid 14 may include a potentially corrosive material (e.g., to a protective coating overlying a magnetic material in a permanent magnet) useful in substrate processing like an etchant. Examples of suitable etchant include halogen-containing like chlorine-containing materials such as chlorine (Cl₂) gas and hydrochloric (HCl) acid as well as fluorine-containing materials such as fluorine (F₂) gas and hydrofluoric (HF) acid. In accordance with certain examples, the second fluid 16 may include a potentially disintegrative material (e.g., to a bulk magnetic material formed using a sintering technique) such as certain diluent/carrier fluids also useful in substrate processing. Examples of suitable diluent/carrier fluids include nitrogen (N₂) gas and hydrogen (H₂) gas as well as mixtures containing either (or both) nitrogen (N₂) gas and hydrogen (H₂) gas. It is contemplated that the third fluid 18 may include a material layer precursor useful in substrate processing such as a silicon-containing material employed in the deposition of epitaxial material layers using CVD techniques as well as metal-containing materials employed in the deposition metal layer using ALD techniques. Examples of suitable silicon-containing material layer precursors include silane (SiH₄) and dichlorosilane (H₂SiCl₂); examples of suitable metal containing materials include trimethylaluminum (Al₂(CH₃)₆) and TEMAH ([CH₃](C₂H₅)N)₄Hf). As will be appreciated by those of skill in the art in view of the present disclosure, other material layer precursors may be employed and remain within the scope of the present disclosure.

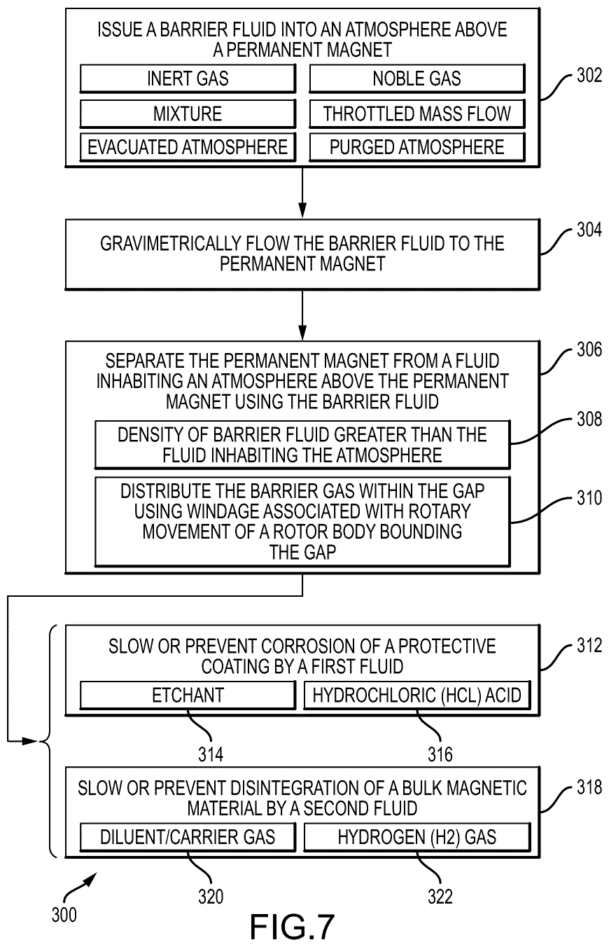

The controller 118 is operably connected to the semiconductor processing system 100 and includes a device interface 156, a processor 158, a user interface 160, and a memory 162. The device interface 156 communicatively couples the processor 158 to the semiconductor processing system 100, such as through a wired or wireless link 164. The processor 158 is connected to the device interface 156 and therethrough to the semiconductor processing system 100, is operably connected to the user interface 160 to receive user input and/or provide user output therethrough and is disposed in communication with the memory 162. The memory 162 includes a non-transitory machine-readable medium having a plurality of program modules 166 recorded on the medium that, when read by the processor 158, cause the processor 158 to execute certain operations. Among the operations are operations of a method 300 (shown in FIG. 7) of purging a motor arrangement, e.g., the motor arrangement 200, as will be described. Although shown and described herein as having a specific architecture it is to be understood and appreciated that the architecture shown and described herein is for illustration and description purpose only, and that the controller 118 may have other architectures, e.g., a distributed architecture, in other examples of the present disclosure.

As has been explained above, potentially corrosive and/or disintegrative fluids can, in some semiconductor processing system, limit the reliability of the semiconductor processing system employed the fluid. Without being bound by a particular theory or mode of operation, it is believe that certain fluids may resist removal from process spaces following processing, and consequently infiltrate non-process spaces within the semiconductor processing system. Once resident within such non-process spaces the fluids may corrode and/or disintegrate components and structures employed in substrate processing, such as by corroding and disintegrating permanent magnets include in motor arrangements employed to drive substrate transfer robots. To harden the semiconductor processing system 100 against such infiltrant fluids, and avoid the need for more costly and/or disruptive infiltrant fluid countermeasures, the semiconductor processing system 100 includes the motor arrangement 200.

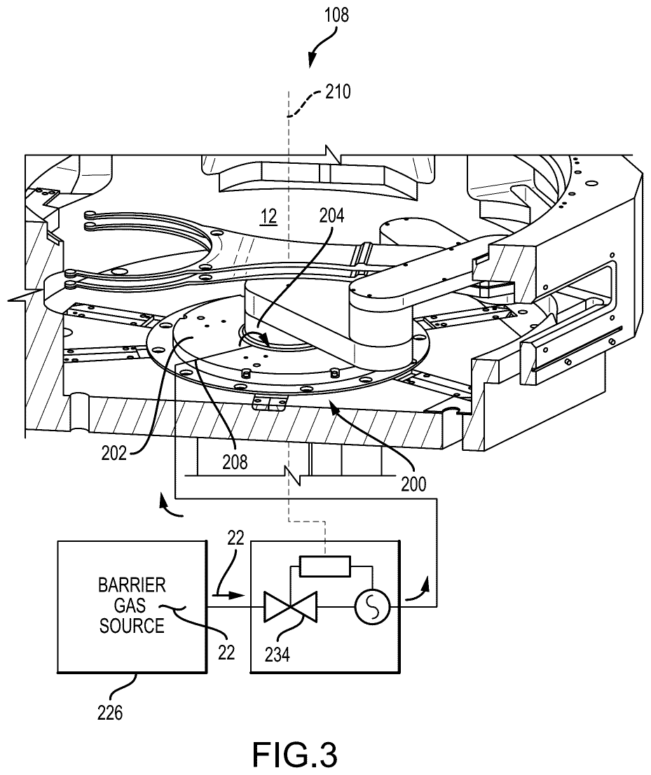

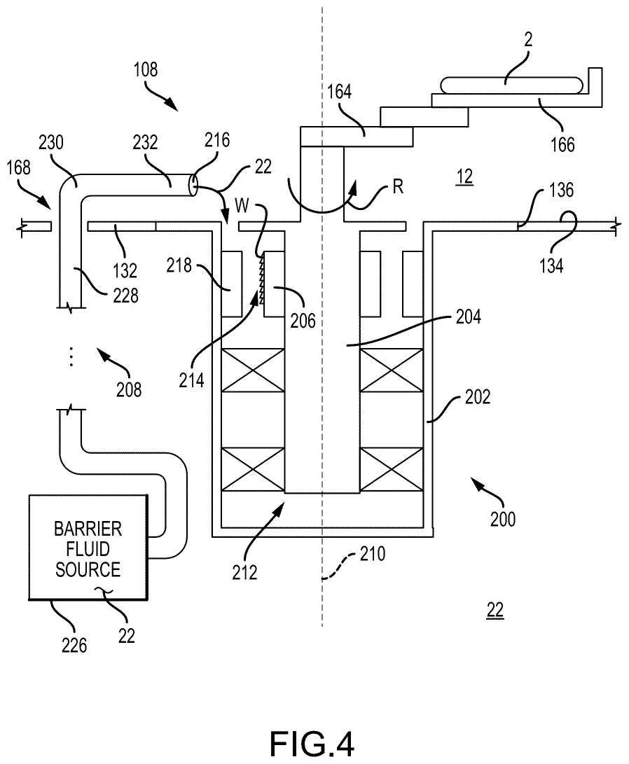

With reference to FIGS. 3-6, the motor arrangement 200 is shown. As shown in FIG. 3, the motor arrangement 200 includes a stator body 202, a rotor body 204 (shown in FIG. 4), a permanent magnet 206 (shown in FIG. 4) and a fluid conduit 208. The stator body 202 defines a rotary axis 210 and has a bore 212 (shown in FIG. 4). The rotor body 204 is supported for rotary movement R about the rotary axis 210 in the bore 212 and is separated from the stator body 202 by a gap 214 (shown in FIG. 4). The permanent magnet 206 is arranged within the gap 214 and is fixed to one of the stator body 202 and the rotor body 204. The fluid conduit 208 has an outlet 216 (shown in FIG. 4) and is supported above the gap 214 such that the outlet 216 is in fluid communication with the gap 214 to issue a barrier fluid 22 into the gap 214 to separate the permanent magnet 206 from an infiltrant fluid, e.g., one or more of the first fluid 14 (shown in FIG. 2) and the second fluid 16 (shown in FIG. 2), resident within the atmosphere 12 above the gap 214. Although shown and described herein as having certain elements, it is to be understood and appreciated that the motor arrangement 200 may include additional elements and/or exclude certain elements shown and described herein and remain within the scope of the present disclosure.

A shown in FIG. 4, the stator body 202 may be formed from electrical steel and in this respect may include a plurality of laminated electrical steel sheets axially stacked with one another along the rotary axis 210. The bore 212 may be a blind bore, the bore opening only toward the atmosphere 12 contained within the substrate transfer chamber body 132 through the gap 214 and being sealed at an end axially opposite the gap 214. The stator body 202 may further include an annular flange portion and a cylindrical portion. The annular flange portion may extend circumferentially about the rotary axis 210 and have a fastener pattern. The fastener pattern may in turn be configured to sealably fix the stator body 202 to the lower wall 134 of the substrate transfer chamber body 132 at the robot seat 136. The cylindrical portion of the stator body 202 may protrude below the substrate transfer chamber body 132 and contain the permanent magnet 206. It is contemplated that the cylindrical portion of the stator body 202 further separate the atmosphere 12 contained within the substrate transfer chamber body 132 from an external environment 24 outside the semiconductor processing system 100.

The rotor body 204 may similarly be formed from electrical steel and further include a laminated stack of sheets axially stacked along the rotary axis 210. The rotor body 204 may be generally circular in shape, the gap 214 thereby being radially offset from the rotary axis 210 and generally in annular shape, and may further extend axially from bore 212 into the atmosphere 12 above the gap 214 and contained within the substrate transfer chamber body 132. In this respect the rotor body 204 may be radially overlapped by the flange portion of the stator body 202, have a permanent magnet or winding-carrying portion extending below the lower wall 134 to the substrate transfer chamber body 132, and have a pillar portion protruding into the substrate transfer chamber body 132 above the flange portion of the stator body 202. It is contemplated that the one or more link 138 pivotably depend from the pillar portion of the rotor body 204, and the that the end effector 140 be connected to the one or more link 138 to carry the substrate 2 within the atmosphere 12 contained with the substrate transfer chamber body 132 above the gap 214 defined between the stator body 202 and the rotor body 204. The rotor body 204 may be supported within the bore 212 by a bearing arrangement including one or more bearing.

The permanent magnet 206 may be fixed to one of the stator body 202 and the rotor body 204 and cooperate with a winding 218. In the illustrated example the permanent magnet 206 is fixed to the rotor body 204 and the winding 218 is fixed to the stator body 202. As will be appreciated by those of skill in the art in view of the present disclosure, fixing the permanent magnet 206 to the rotor body 204 and the winding 218 to the stator body 202 can simplify the motor arrangement 200, for example by simplifying the provision of power to the motor arrangement 200 by limiting need to fix a power cable to the rotor body 204 to rotate the rotor body 204. As will also be appreciated by those of skill in the art in view of the present disclosure, the permanent magnet 206 may be fixed to the stator body 202 and remain within the scope of the present disclosure. In certain examples, the permanent magnet 206 may be one of a plurality of permanent magnets 206 arranged within the gap 214 and distributed circumferentially about the rotary axis 210. In accordance with certain examples, the winding 218 may be one of a plurality of windings arranged within the gap 214, fixed to the stator body 202, and distributed circumferentially about the rotary axis 210.

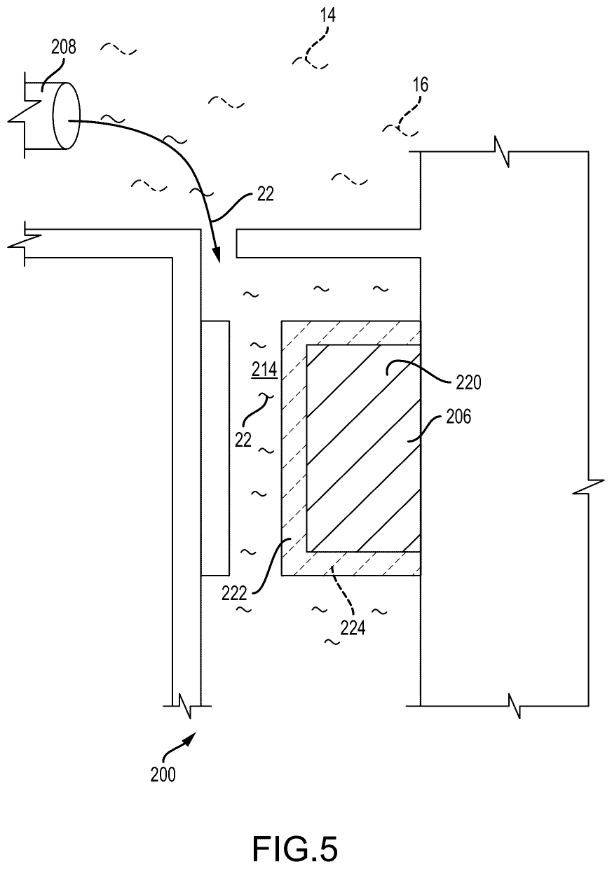

As shown in FIG. 5, the permanent magnet 206 may be formed from a bulk magnetic material 220 and have a coating 222. The bulk magnetic material 220 may include (or consist of or consist essentially of) an alloy made from a rare-earth metal. In this respect the bulk magnetic material 220 may be formed from an alloy including one or more of praseodymium (Pr), neodymium (Nd), samarium (Sm), gadolinium (Gd), terbium (Tb), dysprosium (Dy) and holmium (Ho). The bulk magnetic material 220 may formed using a sintering or bonding technique. In certain examples, the alloy forming the bulk magnetic material 220 may include (or consist of or consist essentially of) Nd₂Fe₁₄B alloy. In accordance with certain examples, the alloy forming the bulk magnetic material 220 may include (or consist of or consist essentially of) SmCo₅ or Sm(Co,Fe,Cu,Zr) y alloy. As will be appreciated by those of skill in the art in view of the present disclosure, forming the permanent magnet 206 from the bulk magnetic material 220 may impart the permanent magnet 206 with relatively a relatively strong magnetic field, imparting relatively high torque over an operation range of the motor arrangement and limiting size of the motor arrangement in relation to size and weight of the one or more link 138 and the one or more end effector 140.

The coating 222 may be configured to protect the bulk magnetic material 220 from the operating environment of the permanent magnet 206, from example from fluids resident within the gap 214. In this respect it is contemplated that the coating 222 may overlie the bulk magnetic material 220 and separate the bulk magnetic material 220 from fluids resident within the gap 214. In certain examples, the coating 222 may include a coating material 224 that is resistant to corrosion such as nickel (Ni), zinc (Zn), silver (Ag), copper (Cu), gold (Au), and combinations thereof as well as epoxy, black nickel, chrome (Cr), rubber, polytetrafluoroethylene (C₂F₄)ₙ, and titanium nitride (TiN). As will be appreciated by those of skill in the art in view of the present disclosure, coating materials such as these can limit (or prevent) exposure of the bulk magnetic material 220 to fluids resident within the gap 214, prolonging the service life of the motor arrangement 200 in environments containing such fluids. In certain examples of the present disclosure the coating 222 may deposited using an electroplating technique, e.g., using electrochemical deposition or electrodeposition, and in this respect may be a plating.

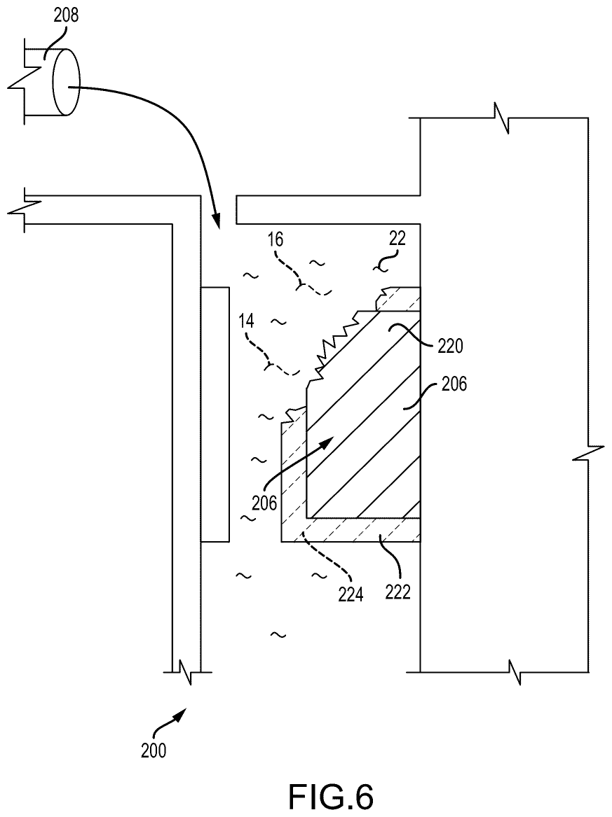

As shown in FIG. 6, certain types of permanent magnets may degrade during service when employed in environments containing relatively small amounts of hydrochloric (HCl) acid and hydrogen (H₂) gas, as can exist in within interior of the substrate transfer chamber body 132 when the semiconductor processing system 100 (shown in FIG. 1) is employed to deposit certain material layers and/or remove material from certain types of substrates. For example, permanent magnets coated with materials like nickel (Ni) may corrode responsive to exposure to the hydrochloric (HCl) acid resident in the permanent magnet operating environment, exposing the underlying bulk magnetic material to the operating environment. Once exposed, bulk magnetic materials including sintered neodymium alloys (Nd₂Fe14B) may disintegrate (e.g., de-sinter) responsive to exposure to the hydrogen (H₂) gas resident in the permanent magnet operating environment, limiting reliability of the motor arrangement and the substrate transfer driven by the motor arrangement. With respect to such permanent magnets, introduction of relatively small mass flow amounts of the barrier fluid 22 into the gap 214 provides sufficient separation of the permanent magnet 206 corrosive and disintegrative fluids like the first fluid 14 and the second fluid 16 such the time required for corrosion of the coating 222 and disintegration of the bulk magnetic material 220 exceeds the expected service life of the motor arrangement 200 and the back-end substrate transfer robot 130 driven by the motor arrangement 200. Advantageously, this avoids the need to replace motor arrangements employed in such environments with motor arrangements having permanent magnets formed from other alloys by providing the barrier fluid 22 using the fluid conduit 208, the motor arrangement 200 never reaching the condition shown in FIG. 6 while installed in the semiconductor processing system 100 (shown in FIG. 1), enabling motor arrangements formed from nickel-plated neodymium (Nd₂Fe₁₄B) alloy to reach their expected service life.

Referring again to FIG. 2, it is contemplated that the fluid conduit 208 connect a barrier fluid source 226 to the substrate transfer module 108. More specifically, the fluid conduit 208 may connect the barrier fluid source 226 to the substrate transfer chamber body 132 containing the motor arrangement 200. In this respect it is contemplated that the fluid conduit 208 fluidly couple the barrier fluid source 226 to the atmosphere 12 and therethrough to the gap 214 (shown in FIG. 4) defined between the stator body 202 (shown in FIG. 4) and the rotor body 204 (shown in FIG. 4) within which the permanent magnet 206 is arranged. In further respect, the barrier fluid source 226 includes the barrier fluid 22 and is configured to provide a flow of the barrier fluid 22 to the substrate transfer module 108 wherein the barrier fluid 22 may gravimetrically flow into the gap 214 and separate the permanent magnet 206 from fluids resident within the atmosphere 12 above gap 214, for example the first fluid 14 and the second fluid 16.

In certain examples the barrier fluid 22 may have a density that is greater than a density of an infiltrant fluid resident within the atmosphere 12 contained within the substrate transfer chamber body 132. In this respect the barrier fluid 22 may have a density that is greater than a density of the first fluid 14 under the pressure and temperature conditions (e.g., in an evacuated atmosphere at about room temperature) maintained within the interior of the substrate transfer chamber body 132 during processing. In further respect, the barrier fluid 22 may have a density that is greater than a density of the second fluid 16 under the pressure and temperature conditions (e.g., in an evacuated atmosphere at about room temperature) maintained within the interior of the substrate transfer chamber body 132 during processing. It is also contemplated that the barrier fluid 22 may have a greater density than both the first fluid 14 and the second fluid 16 when intermixed with one another as infiltrant fluids within the atmosphere 12 within the interior of the substrate transfer chamber body 132. As will be appreciated by those of skill in the art in view of the present disclosure, this allows that barrier fluid 22 to gravimetrically flow into the gap 214 defined between the stator body 202 and the rotor body 204 from the outlet 216 of the fluid conduit 208, displacing the first fluid 14 and/or second fluid 16 that may have infiltrated the substrate transfer chamber body 132 and become resident within the gap 214 and creating a barrier between infiltrating fluids and the permanent magnet 206 during processing. Advantageously, such relatively dense barrier fluids can limit (or prevent) fluids potentially corrosive to the coating 222 overlaying the bulk magnetic material 220 forming the permanent magnet 206, such as hydrochloric (HCl) acid. To further advantage, relatively dense barrier fluids can also discourage the rate at which infiltrate fluids potentially dis-integrative fluids such as hydrogen (H₂) gas may enter the gap 214 during processing, limiting the rate at which such fluids may cause exposed magnetic materials to de-sinter during processing. Examples of suitable barrier fluids include inert fluids such as nitrogen (N₂) gas as well as noble gases like helium (He), argon (Ar), neon (Ne), and krypton (Kr). In accordance with certain examples, the barrier fluid 22 may include (or consist of or consist essentially of) argon (Ar) gas.

In certain examples, a barrier fluid supply valve 234 may couple the barrier fluid source 226 to the substrate transfer chamber body 132. The barrier fluid supply valve 234 may be arranged along the fluid conduit 208 and configured to control mass flow rate of the barrier fluid 22 to the atmosphere 12 within the substrate transfer chamber body 132. In accordance with certain example, the barrier fluid supply valve 234 may include a manual actuator, the barrier fluid supply valve 234 being a manual valve in such examples. As will be appreciated by those of skill in the art in view of the present disclosure, manual actuator may simplify setup and operation of the semiconductor processing system 100, for example by limiting cost and complexity associated with separating the permanent magnet 206 (shown in FIG. 4) from fluid resident (e.g., either or both the first fluid 14 and the second fluid 16) within the atmosphere 12 contained within the interior of the substrate transfer chamber body 132.

Referring again to FIG. 3, the barrier fluid supply valve 234 may include an actuator in certain examples of the present disclosure. The actuator may be operably associated with the controller 118 for controlling mass flow rate of the barrier fluid 22 provided to the substrate transfer chamber body 132 according one or more of plurality of program modules 166 (shown in FIG. 2) recorded on the memory 162 (shown in FIG. 2) of the controller 118. Advantageously, incorporating an actuator on the barrier fluid supply valve 234 can limit cost of separating the permanent magnet 206 from fluid resident within the atmosphere 12, for example by synchronizing mass flow rate of the barrier fluid 22 with a scheduling module included among the plurality of program modules 166 recorded on the memory 162 to throttle mass flow rate of the barrier fluid 22 according to movement of substrates through the substrate transfer module 108. As will be appreciated by those of skill in the art in view of the present disclosure, concentration of fluid within the atmosphere 12 may increase and decrease according to frequency of the opening and closing events of the process module gate valve 116 (shown in FIG. 2), and mass flow rate of the barrier fluid 22 may be therefore be reduced (or cease entirely) during intervals within which substrate processing is relatively slow or the semiconductor processing system 100 idle. In accordance with certain examples, the barrier fluid supply valve 234 may be included within a mass flow controller (MFC) device 236 operatively associated with the controller 118 to accomplish the aforementioned throttling.

Referring again to FIG. 4, it is contemplated that the fluid conduit 208 may have a source segment 228, a union or arcuate segment 230 and a supply segment 232. The source segment 228 of the fluid conduit 208 may couple the fluid conduit 208 to the barrier fluid source 226. The source segment 228 may extend vertically through a passthrough 168 defined with the lower wall 134 of the substrate transfer chamber body 132 and be substantially parallel to the stator body 202 of the motor arrangement 200. It is contemplated that the source segment 228 of the fluid conduit 208 may be sealably received within the passthrough 168 (e.g., a bunghole) defined within the lower wall 134 of the substrate transfer chamber body 132.

The union or arcuate segment 230 of the fluid conduit 208 is connected to the source segment 228 and supported within the interior of the substrate transfer chamber body 132. The union or arcuate segment 230 further couples the source segment 228 of the fluid conduit 208 to the supply segment 232 of the fluid conduit 208. In certain examples, the union or arcuate segment 230 of the fluid conduit 208 may have an arcuate sweep of about 90-degrees. In accordance with certain examples, the union or arcuate segment 230 may include threads to threadedly couple the source segment 228 to the supply segment 232 of the fluid conduit 208. In accordance with certain examples, the union or arcuate segment 230 may be integral with either (or both) of the source segment 228 and the supply segment 232 of the fluid conduit 208. Advantageously, examples of the union or arcuate segment 230 having threads enable adjustment of position of the outlet 216 to the gap 214, for example according to the number of process modules employing potentially corrosive and/or disintegrative fluids, allowing the outlet 216 to be position more closely to the gap 214 in semiconductor processing systems expected to harbor greater concentration of such fluids within the atmosphere 12 than systems with fewer process modules employing such fluids.

The supply segment 232 of the fluid conduit 208 is supported above the lower wall 134 of the substrate transfer chamber body 132. The supply segment 232 may further extend about the stator body 202 such that the outlet 216 is between the robot seat 136 and rotary axis 210. In certain examples, the supply segment 232 may position the outlet 216 of the fluid conduit 208 between the gap 214 and the robot seat 136. In accordance with certain examples, the supply segment 232 may position the outlet 216 at a location overlaying the gap 214. It is also contemplated that, in accordance with certain examples of the present disclosure, the supply segment 232 may position the outlet 216 at a location between an opening into the gap 214 and the rotary axis 210. As will be appreciated by those of skill in the art, differing placements of the outlet 216 relative to the gap 214 enables limiting mass flow rate of the barrier fluid 22 according to the rate at which gravity pulls the barrier fluid 22 issued at the outlet 216 according to the tendency of movement of the substrate transfer robot 124 to interfere with the flow.

Referring once again to FIGS. 2 and 4, it is contemplated that the fluid conduit 208 be configured to position the outlet 216 between the loadlock module 106 and the back-end substrate transfer robot 130. Advantageously, positioning the outlet 216 between the loadlock module 106 and the back-end substrate transfer robot 130 enables employing windage W within the gap 214 between the stator body 202 and the rotor body 204 associated with operation of the motor arrangement 200 to distribute the barrier fluid 22 within the gap 214. Specifically, since substrate movement through substrate transfer modules in cluster-type platforms such as the semiconductor processing system 100 may require more rotary movements to the loadlock module 106 than to any one of the plurality of process modules serviced by the back-end substrate transfer robot 124, introduction of the barrier fluid 22 at a location between the loadlock module 106 and the back-end substrate transfer robot 130 promotes distribution of the barrier fluid 22 from locations within the gap 214 proximate the outlet 216 to more regions of the gap 214 distal or remote from the outlet 216, limiting the mass flow of the barrier fluid 22 required separate the permanent magnet 206 during rotary movement R about the rotary axis 210 due to friction between the barrier fluid 22 and the permanent magnet 206. This enables the fluid conduit 208 to provide the barrier fluid 22 from a single outlet, avoiding the need for a distribution manifold, thereby simplifying the motor arrangement 200.

With reference to FIGS. 7-10, the method 300 of purging a motor arrangement, e.g., the motor arrangement 200 (shown in FIG. 1), is shown. As shown in FIG. 7, the method 300 includes issuing a barrier fluid from an outlet of a fluid conduit into an atmosphere above a gap defined between a stator body and a rotor body, e.g., issuing the barrier fluid 22 (shown in FIG. 2) into the atmosphere 12 (shown in FIG. 2) above the gap 214 (shown in FIG. 4) between the stator body 202 (shown in FIG. 4) and the rotor body 204 (shown in FIG. 4), as shown with box 302. The method 300 also includes gravimetrically flowing (and/or diffusing) the barrier gas into the gap defined between the stator body and the rotor body, as shown with box 304. The method 300 further includes separating the permanent magnet from fluids resident within a substrate transfer chamber body, e.g., the substrate transfer chamber body 132 (shown in FIG. 2), as shown with box 306. In this respect it is contemplated that the barrier fluid may have a density that is greater than a density of the fluid in the atmosphere above the gap, as shown with box 308. In further respect, separating the fluid in the atmosphere above the gap from the permanent magnet using the barrier fluid may include distributing the fluid using windage associated with rotary movement of the rotor body bounding the gap, for example during transfer of substrates between the process module 110 (shown in FIG. 1) and the loadlock module 106 (shown in FIG. 1), as shown with box 310.

In certain examples, separating the permanent magnet from the fluid may slow or prevent entirely corrosion of a protective coating overlying a bulk magnetic material forming the permanent magnet by a first fluid, e.g., corrosion of the coating 222 (shown in FIG. 4) overlying the bulk magnetic material 220 (shown in FIG. 4) by the first fluid 14 (shown in FIG. 2), as shown with box 312. In this respect it is contemplated that the coating may include nickel (Ni), zinc (Zn), silver (Ag), copper (Cu), gold (Au) and combinations thereof as well as epoxy, black nickel, chrome (Cr), rubber, polytetrafluoroethylene (C₂F₄)ₙ, and titanium nitride (TiN).]. The first fluid may include an etchant. For example, the first fluid may include a halide-containing material such as hydrochloric (HCl) acid as well as a fluorine-containing material, as shown with box 314 and box 316. In accordance with certain examples, the separating the permanent magnet from the fluid may include slowing or preventing disintegration (e.g., de-sintering) of the bulk magnetic material from a fluid resident in the atmosphere above the gap housing the permanent magnet, e.g., from the second fluid 16 (shown in FIG. 2), as shown with box 318. In this respect it is contemplated that the bulk magnetic material may include alloy containing a rare-earth metal such as praseodymium (Pr), neodymium (Nd), samarium (Sm), gadolinium (Gd), terbium (Tb), dysprosium (Dy) and holmium (Ho). Examples of such rare-earth metal-containing alloys include neodymium (Nd₂Fe₁₄B) alloys. In further respect, the second fluid may include a diluent/carrier gas employed in processing the substrate within the process module attached the substrate transfer chamber body housing the motor arrangement including the permanent magnet, as shown with box 320. Examples of such diluent/carrier gases include nitrogen (N₂) gas, hydrogen (H₂) gas, and mixtures include either (or both) nitrogen (N₂) gas and hydrogen (H₂) gas, as shown with box 322.

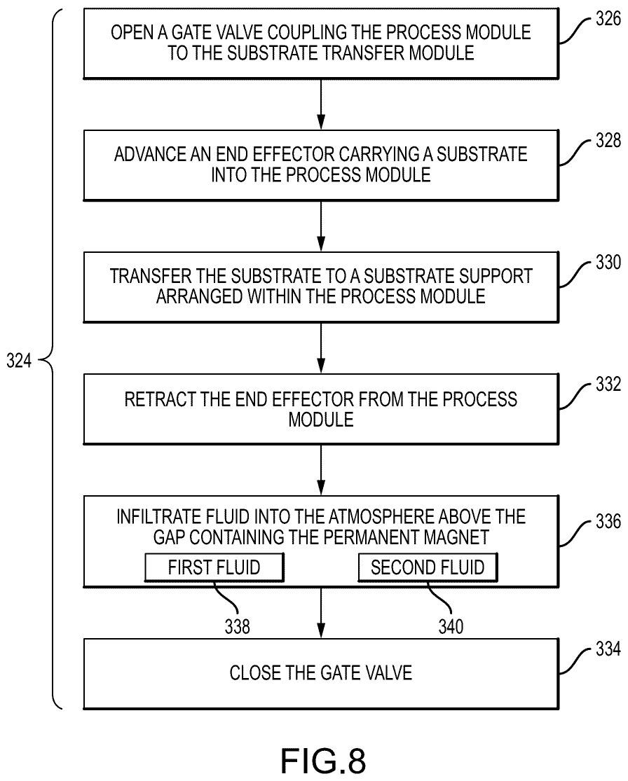

As shown in FIG. 8, the method 300 (shown in FIG. 7) may include infiltrating the fluid into substrate transfer module during loading a substrate into the process module, e.g., the substrate 2 (shown in FIG. 1) into the process module 110 (shown in FIG. 1), as shown with bracket 324. The fluid may infiltrate the substrate transfer chamber body during opening of a gate valve coupling the process module to the substrate transfer module, e.g., the process module gate valve 116 (shown in FIG. 2), as shown with box 326. The fluid may infiltrate the substrate transfer module during advancement of an end effector carrying the substrate into the process module while the gate valve is open, e.g., the one or more end effector 140 (shown in FIG. 1), as shown with box 328. The fluid may infiltrate the substrate transfer module during transfer of the substrate from the end effector to a substrate support arranged within the process module while the gate valve is open, e.g., the substrate support 144 (shown in FIG. 2), as shown with box 330. And the fluid may infiltrate the substrate transfer module during withdrawal of the end effector from the process module while the gate valve is open and/or during closure of the gate valve coupling the process module to the substrate transfer module, as shown with box 332 and box 334. As will be appreciated by those of skill in the art in view of the present disclosure, the fluid may infiltrate the substrate transfer module during the interval within which the gate valve is open, as shown with box 336. As will also be appreciated by those of skill in the art in view of the present disclosure, the end effector may also itself carry fluid into the substrate transfer module to effect the infiltration, such as when fluid condenses on the end effector and/or is absorbed into the material forming the end effector and thereafter adsorbed from the material forming the end effector subsequent to retraction of the end effector from the process module, as also shown with box 336.

In certain examples the first fluid may infiltrate the substrate transfer module during loading of the substrate into the process module, as shown with box 338. In accordance with certain examples, the second may fluid may infiltrate the substrate transfer module during loading of the substrate into the process module, as shown with box 340. It is also contemplated that both the first fluid and the second fluid may infiltrate the substrate transfer module during loading of the substrate into the process module, as also shown by box 338 and box 340.

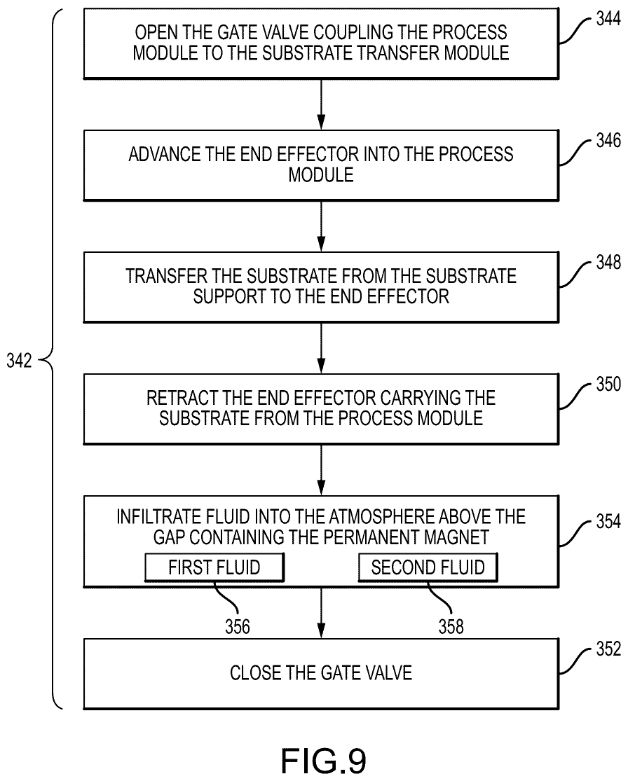

As shown in FIG. 9, the method 300 (shown in FIG. 7) may include infiltrating the fluid into substrate transfer module during unloading of the substrate from into the process module, as shown with bracket 342. The fluid may infiltrate the substrate transfer module during opening of a gate valve coupling the process module to the substrate transfer module, as shown with box 344. The fluid may infiltrate the substrate transfer module during advancement of the end effector into the process module while the gate valve is open, as shown with box 346. The fluid may infiltrate the substrate transfer module transfer of the substrate from the substrate support to the end effector while the gate valve is open, as shown with box 348. And the fluid may infiltrate the substrate transfer module during withdrawal of the end effector carrying the substrate while the gate valve is open and/or during closure of the gate valve coupling the process module to the substrate transfer module, as shown with box 350 and box 352. As will be appreciated by those of skill in the art in view of the present disclosure, fluid may infiltrate the substrate transfer module during the interval within which the gate valve is open, for example, due to pressure imbalance between the atmosphere contained within the process module and that contained within the substrate transfer module, as shown with box 354. As will also be appreciated by those of skill in the art in view of the present disclosure, the fluid infiltration may also (or alternatively) be affected by fluid disturbance associated with movement of the end effector and/or due to absorption and subsequent adsorption of fluid from the material forming the end effector as well as the substrate itself, as also shown with box 354.

In certain examples the first fluid may infiltrate the substrate transfer module during unloading of the substrate from the process module, as shown with box 356. In accordance with certain examples, the second may fluid may infiltrate the substrate transfer module during unloading of the substrate from the process module, as shown with box 358. It is also contemplated that both the first fluid and the second fluid may infiltrate the substrate transfer module during unloading of the substrate from the process module, as also shown by box 356 and box 358.

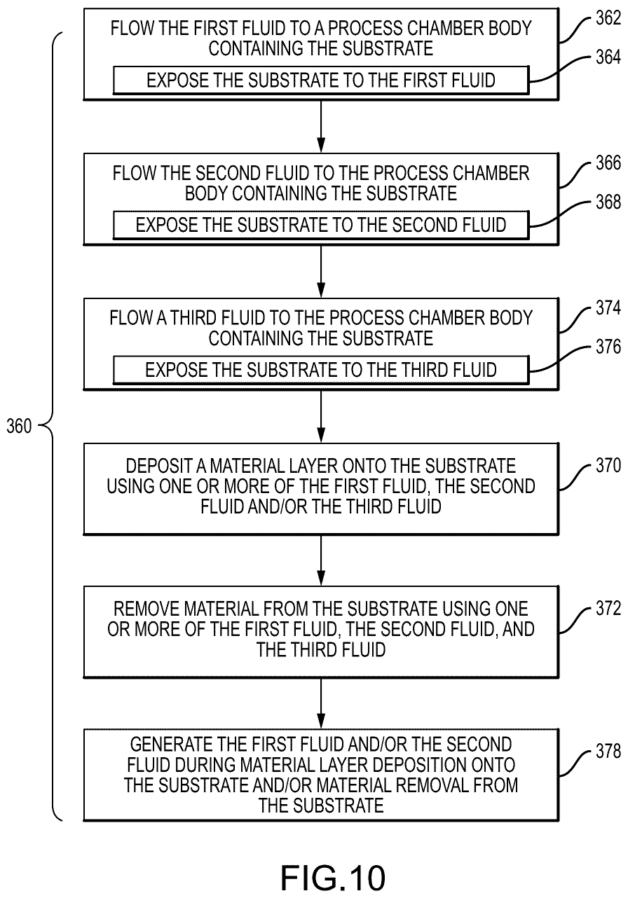

As shown in FIG. 10, infiltrating 324 the fluid into the substrate transfer module during loading of the substrate into the process module and/or infiltrating 342 the fluid into the substrate transfer module during unloading of the substrate from the process module may include processing the substrate using the fluid, as shown with bracket 360. In this this respect it is contemplated that the first fluid may be flowed to a process chamber body containing the substrate from a first fluid source, e.g., the first fluid flowed the process chamber body 142 (shown in FIG. 2) by the first fluid source 150 (shown in FIG. 2), as shown with box 362. Therein the substrate may be exposed to the first fluid, as shown with box 364. At least a portion of the first fluid flowed to the process chamber body may linger within the process chamber body 142 subsequent to processing and thereafter infiltrate the substrate transfer module during the aforementioned loading and unloading of the substrate.

The second fluid may be flowed to a process chamber body containing the substrate from a second fluid source, e.g., the second fluid source 152 (shown in FIG. 2), as shown with box 366. Therein the substrate may be exposed to the second fluid, as shown with box 368, and least a portion of the first fluid flowed to the process chamber body may linger within the process chamber body 142 subsequent to processing and thereafter infiltrate the substrate transfer module during the aforementioned loading and unloading of the substrate. As shown with box 370 and box 372, processing the substrate may include depositing a material layer on the substrate and/or removing material from the substrate using one or more of the first fluid and the second fluid. As shown with box 374 and box 376, a third fluid including a material layer precursor may be flowed to the process chamber and the substrate exposed thereto, e.g., the third fluid 20 (shown in FIG. 2) from the third fluid source 154 (shown in FIG. 2), in examples wherein processing the substrate includes depositing a material layer onto the substrate. In this respect the third fluid may include depositing the material layer using a CVD technique or an ALD technique, as also shown with box 370. In further respect, either (or both) the first fluid and the second fluid may employed in a material removal technique, such as a preclean or surface preparation operation, as also shown with box 372. As will be appreciated by those of skill in the art in view of the present disclosure, either (or both) the first fluid 14 and the second fluid 16 may include a reaction product generated in associate with material layer deposition onto the substrate and/or material removal from the substrate, as shown with box 378.

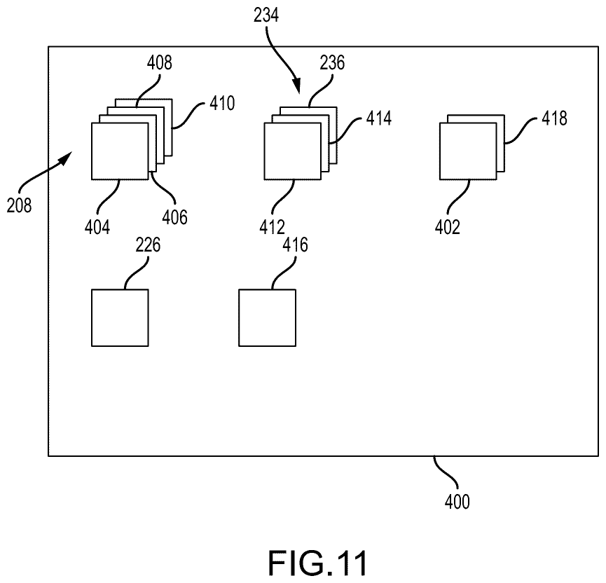

With reference to FIG. 11, a barrier fluid kit 400 for a motor arrangement, e.g., the motor arrangement 200 (shown in FIG. 1), is shown. The barrier fluid kit 400 is configured to provide a barrier fluid purge to the motor arrangement 200 and in this respect includes the fluid conduit 208, the barrier fluid supply valve 234, and a computer program product 402. The fluid conduit 208 is configured to issue the barrier fluid 22 (shown in FIG. 2) into a substrate transfer chamber body, e.g., the substrate transfer chamber body 132 (shown in FIG. 1) from the outlet 216 for gravimetrically flow therefrom to a permanent magnet arranged within a gap defined between a stator body and the rotor body bounding the gap, for example, to the permanent magnet 206 (shown in FIG. 4) within the gap 214 (shown in FIG. 4) bounded by the stator body 202 (shown in FIG. 4) and the rotor body 204 (shown in FIG. 4). In certain examples the fluid conduit 208 may be monolithic in construction, as shown with box 404, the fluid conduit 208 in such examples extending continuously and without a threaded connection between the source segment 228 (shown in FIG. 4) through the union or arcuate segment 230 (shown in FIG. 4) and a supply segment 232 (shown in FIG. 4) to the outlet 216 (shown in FIG. 4). In certain examples the fluid conduit 208 may include one or more of a threaded source segment 406, a threaded union or arcuate segment 408, and a threaded supply segment 410 terminating at the outlet 286.

The barrier fluid supply valve 234 is configured to couple a barrier fluid source containing the barrier fluid 22, e.g., the barrier fluid source 226, the fluid conduit 208. In certain examples the barrier fluid supply valve 234 may include a manual actuator 412. The barrier fluid supply valve 234 may be connected in series with a pressure gauge and arranged as a gas stick to fluidly coupled the barrier fluid source to the fluid conduit 208, as also shown with box 412. In accordance with certain examples, the barrier fluid supply valve 234 may include an actuator 414, such as a solenoid actuator, operatively associated with the barrier fluid supply valve 234 for throttling mass flow rate of the barrier fluid 22 traversing the barrier fluid supply valve 234. It is also contemplated that, in accordance with certain examples, the barrier fluid supply valve 234 may be incorporated in the MFC device 236, for example to cooperate with mass flow target received from the controller 118 and a mass flow meter included in the MFC device 236.

The computer program product 402 may include a non-transitory computer medium having a plurality of program modules recorded on the medium to purge a motor arrangement, e.g., the motor arrangement 200 (shown in FIG. 1), using the barrier fluid 22. The instructions recorded on the medium may cause a controller operatively connected to the barrier fluid supply valve 234 to issue the barrier fluid 22 from the outlet 216 into an atmosphere above a permanent magnet arranged within a gap defined by a stator body and a rotor body, e.g., into the atmosphere 12 (shown in FIG. 2) above the permanent magnet 206 (shown in FIG. 4) arranged within the gap 214 (shown in FIG. 4) defined between the stator body 202 (shown in FIG. 4) and the rotor body 204 (shown in FIG. 4), according to rotary movement of the rotor body about a rotary axis, e.g., the rotary movement R (shown in FIG. 4) about the rotary axis 210 (shown in FIG. 4) such that the barrier fluid 22 gravimetrically flows into the gap 214 and separates the permanent magnet 206 from an infiltrant fluid resident in the atmosphere 12 and potentially corrosive and/or disintegrative to the permanent magnet 206, e.g., the first fluid 14 (shown in FIG. 4) and/or the second fluid 16 (shown in FIG. 4)), as also shown with box 402.

In certain examples, the barrier fluid kit 400 may include the barrier fluid source 226. In accordance with certain examples, the barrier fluid kit 400 may include a passthrough bung 416 configured to sealably fix the fluid conduit 208 within a passthrough defined within a lower wall of the substrate transfer chamber body, for example the passthrough 168 (shown in FIG. 4). It is also contemplated that, in accordance with certain examples, that the computer program product 402 may include a run-in module 418. In such examples the run-in module 418 may be configured to receive a substrate transfer count from a controller operatively associated with a substrate transfer robot, e.g., the controller 118 (shown in FIG. 1) operatively associated with the back-end substrate transfer robot 130 (shown in FIG. 1), compare the substrate transfer count to a predetermined substrate transfer value, and limit (or prevent) flow of the barrier fluid 22 to the substrate transfer chamber when the substrate transfer count is less than the predetermined substrate transfer value to impart roughness into a surface of the permanent magnet 206. As will be appreciated by those of skill in the art in view of the present disclosure, this can limit the mass flow rate of barrier fluid required to separate the permanent magnet from the potentially corrosive and/or disintegrative fluid in the atmosphere above the gap within which the permanent magnet 206 is arranged, for example by increasing the efficacy of the windage distribution described above early in the service life of the back-end substrate transfer robot.

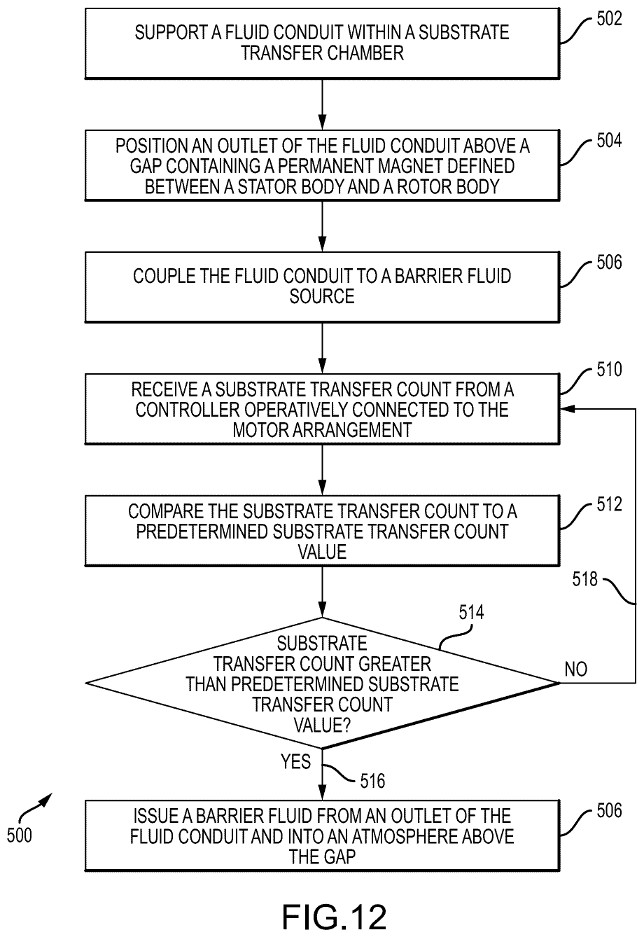

With reference to FIG. 12, a method 500 of making a semiconductor processing system, e.g., the semiconductor processing system 100 (shown in FIG. 1), is shown. The method 500 include supporting a fluid conduit within a substrate transfer chamber body in a substrate transfer chamber body, e.g., the fluid conduit 208 (shown in FIG. 2) in the substrate transfer chamber body 132 (shown in FIG. 2), as shown with box 502. The method 500 further includes positioning an outlet of the fluid conduit above a gap containing a permanent magnet defined between a stator body and a rotor body of a motor arrangement, e.g., above the gap 214 (shown in FIG. 4) containing the permanent magnet 206 (shown in FIG. 4) defined between the stator body 202 (shown in FIG. 4) and the rotor body 202 (shown in FIG. 4), as shown with box 504. The method further includes coupling the fluid conduit to a barrier fluid source and issuing a barrier fluid from the fluid conduit into an atmosphere above the gap, e.g., issuing the barrier fluid 22 (shown in FIG. 2) from the barrier fluid source 226 (shown in FIG. 2) into the atmosphere 12 (shown in FIG. 2), as shown with box 506 and box 508.

In certain examples, the method may further include receiving a substrate transfer count at a controller operably connected to the motor arrangement, e.g., the controller 118 (shown in FIG. 1), as shown with box 510. The controller may compare the substrate transfer count to a predetermined substrate transfer value and delay issue of the barrier fluid into the atmosphere when the substrate transfer count is less that the predetermined substrate transfer value, as shown with box 512 and box 514 and well as with box 516 and box 518. Advantageously, this can delay separation of the permanent magnet from a fluid corrosive to the permanent magnet, improving efficiency of barrier fluid subsequently utilized by increasing roughness (and thereby windage) within the gap subsequent to issuing the barrier fluid into the atmosphere above the gap and therethrough to the gap.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A motor arrangement, comprising:
a stator body defining a rotary axis and having a bore;
a rotor body supported for rotary movement about the rotary axis in the bore, the rotor body separated from the stator body by a gap;
a permanent magnet arranged within the gap and fixed to one of the stator body and the rotor body; and
a fluid conduit supported above the gap and having an outlet in fluid communication with the gap to separate the permanent magnet from an infiltrant fluid resident within an atmosphere above of the gap by issuing a barrier fluid into the atmosphere above the gap and gravimetrically flowing the barrier fluid into the gap.

2. The motor arrangement of claim 1, the bore is a blind bore, wherein the rotor body extends axially from the bore and into the atmosphere above the gap.

3. The motor arrangement of claim 1, wherein the permanent magnet is formed from a magnetic material including neodymium, and wherein the permanent magnet has a nickel coating.

4. The motor arrangement of claim 1, wherein the permanent magnet is one of a plurality of permanent magnets carried by the rotor body distributed circumferentially about the rotary axis.

5. The motor arrangement of claim 1, further including a barrier fluid source including a barrier fluid connected to the fluid conduit and configured to flow the barrier fluid to the outlet.

6. The motor arrangement of claim 5, wherein the barrier fluid has a density greater than that of the infiltrant fluid.

7. The motor arrangement of claim 5, wherein the barrier fluid has a density greater than at least one of hydrochloric (HCl) acid and hydrogen (H₂) gas.

8. The motor arrangement of claim 1, further comprising:
a link pivotably connected to the rotor body and extending laterally from the rotor body within the atmosphere above the gap defined between the stator body and the rotor body; and
an end effector connected the link and configured to carry a substrate within the atmosphere above the gap defined between the stator body and the rotor body.

9. The motor arrangement of claim 1, further comprising a substrate transfer chamber body with a lower wall defining a robot seat, wherein the stator body is fixed to the robot seat and extends below the lower wall of the substrate transfer chamber body.

10. A semiconductor processing system, comprising:
a motor arrangement as recited in claim 1;
a substrate transfer chamber body having a facet and a lower wall defining a robot seat, wherein the stator body of the motor arrangement is fixed within the robot seat;
wherein the stator body protrudes below the lower wall of substrate transfer chamber body;
wherein the rotor body of the motor arrangement protrudes above the lower wall of the substrate transfer chamber body and into an interior of the substrate transfer chamber body; and
wherein the fluid conduit of the motor arrangement is separated from the facet by the rotor body of the motor arrangement.

11. The semiconductor processing system of claim 10, wherein the lower wall of the substrate transfer chamber body defines a passthrough, and wherein the fluid conduit comprises a vertical segment coupled to a horizontal segment by a union or arcuate segment, the vertical segment extending through the passthrough, the union or arcuate segment coupling the vertical segment to the horizontal segment, and the horizontal segment coupling the union or arcuate segment to the outlet of the fluid conduit.

12. The semiconductor processing system of claim 10, further comprising:
a barrier fluid source connected to the fluid conduit and configured to issue a barrier fluid into the interior of the substrate transfer chamber body above the gap defined between the stator body and the rotor body of the motor arrangement; and
a vacuum source connected to the substrate transfer chamber body and configured to evacuate the interior of the substrate transfer chamber body.

13. The semiconductor processing system of claim 10, further comprising:
a first fluid source including a first fluid coupled to the facet;
a second fluid source including a second fluid coupled to the facet;
wherein first fluid contained in the first fluid source is apt to infiltrate the interior of the substrate transfer chamber body and therethrough the gap between the rotor body and the stator of the motor arrangement through the facet of the substrate transfer chamber body; and
wherein second fluid contained in the second fluid source is apt to infiltrate the interior of the substrate transfer chamber body and therethrough the gap between the rotor body and the stator of the motor arrangement through the facet of the substrate transfer chamber body.

14. The semiconductor processing system of claim 13, wherein the permanent magnet includes a protective coating, wherein the first fluid is corrosive to the protective coating, and wherein the first fluid is less dense than the barrier fluid when the first fluid and the barrier fluid reside within an evacuated atmosphere above the gap defined between the stator body and the rotor body.

15. The semiconductor processing system of claim 13, wherein the permanent magnet is formed from a bulk magnetic material, wherein the second fluid is disintegrative to the bulk magnetic material forming the permanent magnet, and wherein the second fluid is less dense than the barrier fluid when the second fluid and the barrier fluid reside within an evacuated atmosphere contained within the interior of the substrate transfer chamber body.

16. The semiconductor processing system of claim 10, wherein the interior of the substrate transfer chamber body contains an evacuated atmosphere, wherein the gap defined between the stator body and the rotor body is in fluid communication with the interior of the substrate transfer chamber body, and wherein the barrier fluid resides within the gap defined between the stator body and the rotor body of the motor arrangement.

17. The semiconductor processing system of claim 16, wherein the permanent magnet is formed from neodymium (Nd) and has a nickel (Ni) coating, wherein infiltrant hydrogen (H₂) gas and hydrochloric (HCl) acid are resident within the evacuated atmosphere contained within the interior of the substrate transfer chamber body, and wherein the barrier fluid include argon (Ar) gas separating the permanent magnet from the infiltrant hydrogen (H₂) gas and the hydrochloric (HCl) acid resident within the evacuated atmosphere contained within the interior of the substrate transfer chamber body.

18. The semiconductor processing system of claim 10, further comprising:
a link pivotably depending from the rotor body;
an end effector depending from the link and configured to carry a substrate;
a process module coupled to the facet of the substrate transfer chamber body, the process module configured to one or more of etch the substrate and deposit a material layer onto the substrate;
wherein the facet is one of a plurality of facets distributed about the robot seat and extending upwards from the lower wall of the substrate transfer chamber body; and
wherein the barrier fluid consists essentially of one of helium (He) gas, argon (Ar) gas, krypton (Kr) gas, neon (Ne) gas, and xenon (Xe) gas.

19. A method of purging a motor arrangement, comprising:
at a motor arrangement including a stator body defining a rotary axis and having a bore, a rotor body supported for rotary movement about the rotary axis in the bore, the rotor body separated from the stator body by a gap, a permanent magnet arranged within the gap and fixed to one of the stator body and the rotor body, and a fluid conduit supported above the gap and having an outlet in fluid communication with the gap,
issuing a barrier fluid from the outlet of the fluid conduit into an atmosphere above the gap;
gravimetrically flowing the barrier fluid into the gap defined between the stator body and the rotor body; and
separating the permanent magnet from an infiltrant fluid potentially corrosive and/or disintegrative to the permanent magnet resident in the atmosphere above of the gap using the barrier fluid to prolong an expected service life of the motor arrangement.

20. A barrier fluid kit for a motor arrangement including a stator body defining a rotary axis and having a bore, a rotor body supported for rotary movement about the rotary axis in the bore, the rotor body separated from the stator body by a gap, and a permanent magnet arranged within the gap and fixed to one of the stator body and the rotor body, the barrier fluid kit comprising;
a fluid conduit with an outlet configured to issue a barrier fluid into a substrate transfer chamber body including the motor arrangement and flow the barrier fluid into the gap between the stator body and the rotor body;
a barrier fluid supply valve configured to couple a barrier fluid source to the fluid conduit and flow the barrier fluid to the fluid conduit; and
a computer program product including instructions recorded on a non-transitory machine readable medium that, when read by a processor operatively connected to the barrier fluid supply valve, cause the barrier fluid supply valve to:
issue a barrier fluid from the outlet of the fluid conduit into an atmosphere above the gap according to rotary movement of the rotor body relative to the stator body about the rotary axis in the bore;
whereby the barrier fluid gravimetrically flows into the gap; and
whereby the barrier fluid separates the permanent magnet from an infiltrant fluid potentially corrosive and/or disintegrative to the permanent magnet resident in the atmosphere above of the gap to prolong an expected service life of the motor arrangement.
